(19) United States
(12) Patent Application Publication
(10) Pub. No.: US 2023/0408549 A1
(43) Pub. Date: Dec. 21, 2023

(54) METHOD FOR CLEANING PROBE TIP AND METHOD AND APPARATUS FOR FORMING PROBE TIP INTO CONICAL SHAPE

(71) Applicant: Probe Innovation, Inc., Hiroshima (JP)

(72) Inventors: Akiko IWANA, Hiroshima (JP); Tadashi ROKKAKU, Irving, TX (US); Masafumi YAMASHITA, Hiroshima (JP)

(73) Assignee: Probe Innovation, Inc., Hiroshima (JP)

(21) Appl. No.: 18/163,751

(22) Filed: Feb. 2, 2023

(30) Foreign Application Priority Data
Jun. 17, 2022 (JP) 2022-108690

(51) Int. Cl. G01R 3/00; B08B 3/12

(52) U.S. Cl. CPC G01R 3/00; B08B 3/12; H01L 22/14

(57) ABSTRACT

Under the conditions that an abrasive cleaning gel film having an abrasive cleaning gel layer and being configured to be stuck to a surface or a container filled with a viscous fluid or a gel fluid in which fine abrasive grains are mixed and dispersed is attached to a vibrating surface of an ultrasonic transducer, and an axial direction of a probe for test is matched with a vibrating direction of the ultrasonic transducer, a tip of the probe is penetrated to a predetermined depth in the abrasive cleaning gel layer or the viscous fluid in which the fine abrasive grains are mixed and dispersed at a constant speed and then pulled up at a constant speed, whereby the tip of the probe can be formed into a conical shape.

### CROSS-REFERENCE TO RELATED APPLICATIONS

This application claims the benefit of priority from Japanese Patent Application No. 2022-108690 filed on Jun. 17, 2022, the entire contents of which are incorporated herein by reference.

### TECHNICAL FIELD

The present invention relates to a method for cleaning a tip of a probe for test and a method and an apparatus for forming the tip into a conical shape.

### BACKGROUND

In recent years, with the spread of power semiconductors and fine pitch semiconductors, test currents for semiconductor electrical test have increased. In addition, due to the request for an increase in the life of the probe for test, rare metals such as rhodium and iridium are becoming popular as probe materials that have a large current-carrying capability and can extend the probe life.

In many cases, a tip of a probe used in the semiconductor electrical test has a conical shape with a sharp edge in order to break an oxide film on a surface of a pad of the semiconductor side for improving contact electrical conduction and because of a small size of the electrode pad.

On the other hand, when the continuity test by the probe is repeatedly performed, the tip having the conical shape is also worn. For this reason, it is necessary to regenerate the conical shape in a timely manner. As a method of regenerating the conical shape, there are roughly a chemical etching method and a mechanical etching method using an abrasive cleaning gel. The conventional method of regenerating the conical shape and its failure will be described with reference to FIGS. 6 and 7.

In FIG. 6, a probe 51 is composed of a straight pin 53 and a conical portion 54 at the edge. A tip 54w in FIG. 6(a) represents a worn conical portion at the edge, and a probe 51w represents a worn probe that requires regeneration.

A container 56 placed on a table 55 is filled with a chemical etchant 57 having a corrosive effect on metals.

When the probe 51w requiring regeneration shown in FIG. 6(a) is lowered in the direction indicated by an arrow 58, the probe is immersed in the chemical etchant 57 from the tip 54w thereof to process the probe at a constant rate. As a result, the time when the tip is immersed in the chemical etchant 57 is longer, and the time when the upper portion of the probe 51w is immersed in the chemical etchant 57 is shorter. Thus, the tip of the probe 51w becomes conical.

Next, as shown in FIG. 6(b), when the probe is lifted at a constant speed in the direction indicated by an arrow 59, the tip of the probe is repaired to become a tip 54r having the conical shape as shown in FIG. 6(b).

The method of regenerating the conical shape of the tip of the probe by the chemical etching method described in FIG. 6 can be applied to a probe made of a highly corrosive material such as a probe made of tungsten. However, such a method cannot be applied to a probe made of a rare metal such as rhodium or iridium, which is a probe whose demand has increased in recent years. This is because the iridium and the rhodium are the rare metals that are difficult to form compounds with other substances, and do not react with corrosive liquid for chemical etching.

There are also many problems in using chemical etchants in semiconductor manufacturing plants. First, cleaning after chemical etching is essential, and cleaning and drying are troublesome. Furthermore, vapors of the corrosive liquid used in the chemical etching may contaminate the air of the semiconductor manufacturing plants.

Next, the mechanical etching method using the abrasive cleaning gel as the conventional method of regenerating the conical shape of the tip of the probe will be described with reference to FIG. 7. In this figure, an abrasive cleaning gel 60 is composed of a fluid 62 which is in the form of a gel with abrasive grains 61 held densely.

The abrasive cleaning gel 60 is supported by a support film 63. Further, an adhesive layer 64 is provided on a back surface of the support film 63. Thus, a protective film (not shown) of the adhesive layer 64, the adhesive layer 64, the support film 63 and the abrasive cleaning gel 60 constitute an abrasive cleaning gel film 65 which is commercially available.

When the probe 51w requiring regeneration shown in FIG. 7(a) is reciprocated in a vertical direction, that is, a direction indicated by an arrow 66 at a constant speed, and the tip 54w of the probe requiring regeneration repeats a touch-down to the abrasive cleaning gel 60. Accordingly, the abrasive grains 61 repeatedly collide with the tip 54w of the probe. As a result, the tip is mechanically etched by the abrasive cleaning gel 60.

The mechanical etching has a large effect on the tip of the probe 51w, while the etching effect is reduced at a portion farther upward from the tip. Therefore, the probe 51w requiring regeneration is shape-repaired to have the conical shape, resulting in the regenerated tip 54r having the conical shape as shown in FIG. 7(b).

However, the mechanical etching using the abrasive cleaning gel as the conventional method described above has a problem that it is not practical because the time required for shape regeneration is very long. In the conventional method, vertical movement of a machine is used as means for reciprocating the probe 51w requiring regeneration in the vertical direction, that is, the direction indicated by the arrow 66 at the constant speed. For example, even if the probe is moved up and down by a high-speed press, 25,000 times of the touch-down are required in order to form the conical shape of the tip of the probe having a diameter of 0.1 mm. Even if this operation is performed by the high-speed press with the speed of 600 times/minute, it takes about 42 minutes. Thus, the abrasive cleaning gel is effective in removing waste adhering to the tip of the probe, but is inefficient and impractical in repairing the conical shape of the worn tip of the probe.

### RELATED ART DOCUMENT

### Patent Document

A search of the prior art for mechanical etching of a probe using ultrasonic vibration and an abrasive cleaning gel was carried out, but no similar prior art was found.

### SUMMARY OF THE INVENTION

### Problems to be Solved by the Invention

The present invention has been made in view of the above-described problems. It is an object of the present invention to provide a method and an apparatus that are effective in a semiconductor manufacturing site to reduce the downtime of an expensive prober that plays a central role in semiconductor electrical test by performing a method for cleaning a worn-deteriorated tip of a probe used for the semiconductor electrical test and regenerating or repairing the worn-deteriorated tip to be formed into a conical shape with high efficiency in a short time and reducing an adverse effect on an environment of the semiconductor manufacturing site.

### Means of Solving the Problems

According to claim 1 of the present invention, under the conditions that an abrasive cleaning gel film having an abrasive cleaning gel layer and being configured to be stuck to a surface is adhered to a vibrating surface of an ultrasonic transducer and is ultrasonically vibrated, and an axial direction of a probe for test is matched with a vibrating direction of the ultrasonic transducer, an operation, in which a tip of the probe is penetrated to a predetermined depth in the abrasive cleaning gel layer at a constant speed and then pulled up at a constant speed, is performed one or more times to clean the tip of the probe and form the tip of the probe into a conical shape.

Further, according to claim 2 of the present invention, under the conditions that a container having a shallow bottom is fixed to a vibrating surface of an ultrasonic transducer and is filled with a viscous fluid or a gel fluid in which fine abrasive grains are mixed and dispersed to form a viscous fluid or gel fluid layer therein, and an axial direction of a probe for test is matched with a vibrating direction of the ultrasonic transducer, an operation, in which a tip of the probe is penetrated to a predetermined depth in the viscous fluid or gel fluid layer at a constant speed and then pulled up at a constant speed, is performed one or more times to clean the tip of the probe and form the tip of the probe into a conical shape.

### Effects of the Invention

According to the present invention, it is possible to dramatically increase the moving speed of the abrasive grains to be subjected to the mechanical etching with the abrasive cleaning gel. For example, in a case where the high-speed press of the conventional method is used, under the conditions that the amplitude of the vertical movement is 5 mm (both amplitudes) and the rotational speed is 600 rpm, the average speed of the vertical movement is V=rω/(√2)=2.5 mm×2π×10/sec/(√2)=157 mm/sec.

On the other hand, according to the present invention using the ultrasonic vibration, under the conditions that the amplitude of the ultrasonic vibration is 30 microns (both amplitudes) and the frequency is 25 kHz, the moving speed of the abrasive grains for the etching is V=RΩ=0.015 mm×2π×25000/sec/(√2)=1,655 mm/sec.

That is, the effect of mechanical etching can be expected to be increased by a factor of 10 or more. In other words, according to the present invention, even if the test is stopped in order to repair the shape of the tip of the probe, the downtime of the expensive prober is reduced, and the operating rate of the semiconductor production is increased.

Further, as an effect of the present invention, there is also an effect that the time for cleaning the tip of the probe is shortened. In the semiconductor electrical test, a portion of an electrode pad material of a semiconductor adheres to the tip of the probe as waste (debris). This deposit increases a contact resistance value of the probe with respect to the pad and causes erroneous determination. For this reason, the tip of the probe is periodically cleaned. This cleaning time is also reduced.

### BRIEF DESCRIPTION OF THE DRAWINGS

FIG. 1 is an explanatory view of a probe head configuration incorporating a plurality of wire probes as an application example of the present invention.

FIG. 2 is an explanatory view of a probe-tip-wear example of a probe head incorporating a plurality of wire probes as an application example of the present invention.

FIG. 3 is a state explanatory view at the start of application for explaining a method and an apparatus of the present invention.

FIG. 4 is an explanatory view for behavior of abrasive grains within a gel by ultrasonic vibration for explaining the effects of the present invention.

FIG. 5 is a state explanatory view at the end of application for explaining a method and an apparatus of the present invention.

FIG. 6 is an explanatory view of a chemical etching method as a conventional method for repairing a conical shape of a tip of a probe.

FIG. 7 is an explanatory view of a mechanical etching method using an abrasive cleaning gel as a conventional method for repairing a conical shape of a tip of a probe.

Hereinafter, an embodiment of the present invention will be described in detail with reference to the accompanying drawings.

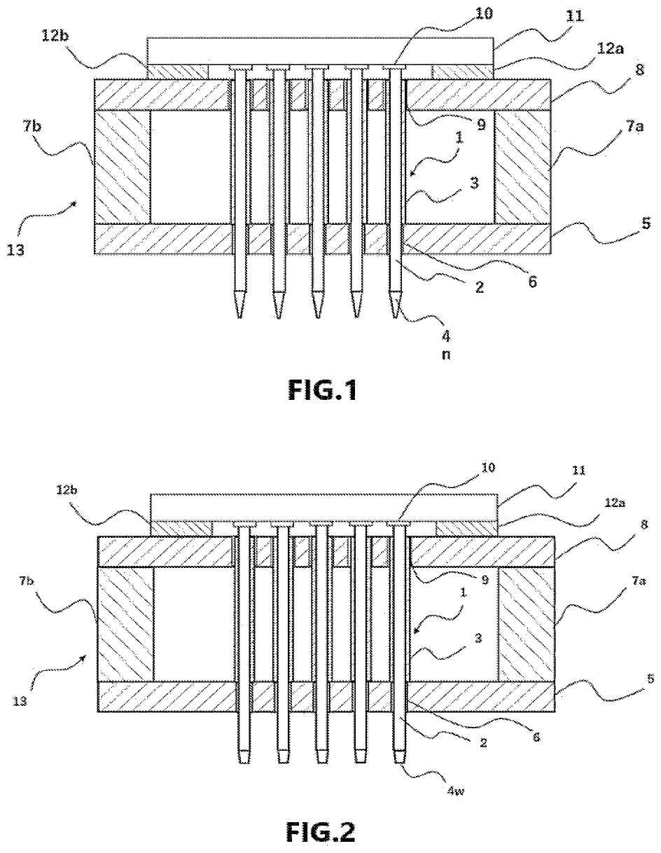

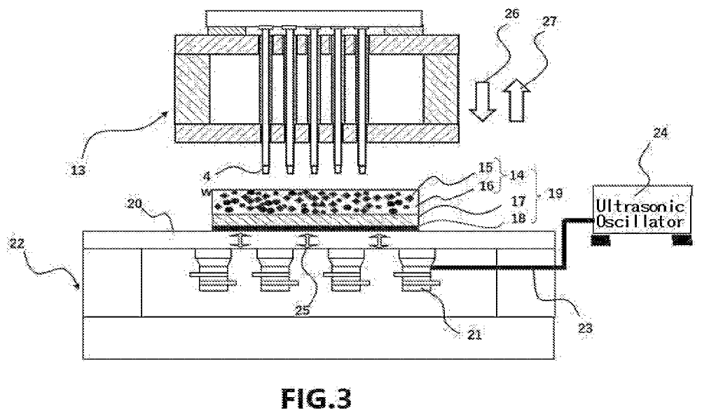

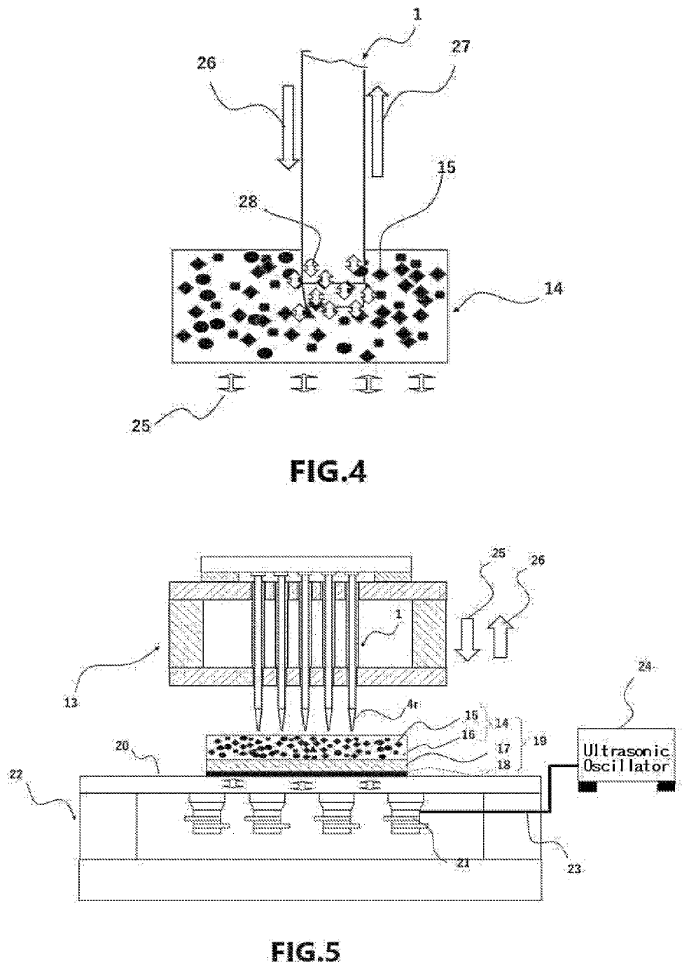

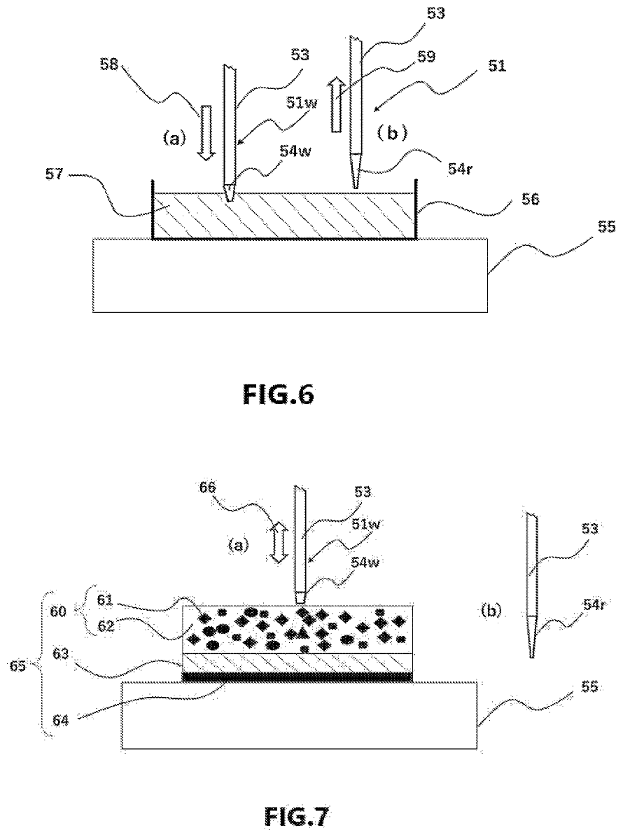

The embodiment of the present invention will be described with reference to FIG. 1, FIG. 2, FIG. 3, FIG. 4 and FIG. 5.

### MODE FOR CARRYING OUT THE INVENTION

FIG. 1 is an explanatory view of a vertical probe head 13 incorporating a wire probe 1 as an application example of the present invention. In FIG. 1, the wire probe 1 is composed of a cylindrical pin 2, an insulating coating 3 and a tip 4n having a conical shape.

A plurality of wire probes 1 are incorporated in the vertical probe head 13. A lower side of the wire probe 1 passes through a through hole 6 of a lower aperture plate 5, and an upper side of the wire probe 1, including the insulating coating 3, passes through a through hole 9 of an upper aperture plate 8. In this regard, the insulating coating 3 also serves to prevent the wire probe 1 from falling.

An upper end of the wire probe 1 is in contact with an upper electrode plate 10 arranged in an orderly manner on a printed circuit board 11. The printed circuit board 11 is fixed to the upper aperture plate 8 by bolts (not shown) via spacers 12a, 12b. Connecting members 7a and 7b connect the upper aperture plate 8 and the lower aperture plate 5.

The tip 4n of the wire probe 1 shown in FIG. 1 is a new product prior to pad test, and therefore has a sharp conical shape. However, if the tip repeatedly contacts several hundred thousand times with an electrode pad (not shown), the tip is worn and loses its sharp shape as shown in the tip 4w of FIG. 2. If the contact continuity test with the electrode pad is continued in this state, the following problems occur.

First, debris from the side of the electrode pad adheres to the tip, increasing the contact resistance. Second, since the tip does not have a sharp conical shape no longer, breaking the oxide film (not shown) on the surface of the electrode pad for the good continuity test cannot be performed.

According to the present invention, it is possible to provide a method for efficiently removing debris (not shown) adhering to the worn tip 4w as described above, and to efficiently restoring the tip shape to the sharp conical shape. Hereinafter, the configurations, operations and effects of the device for realizing the present invention will be described with reference to FIGS. 3, 4, and 5.

In FIG. 3, the abrasive cleaning gel 14 is composed of a fluid 16 which is in the form of a gel with abrasive grains 15 held densely. The abrasive cleaning gel 14 is supported by a support film 17, and further, an adhesive layer 18 is provided on a back surface of the support film 17. Thus, a protective film (not shown) of the adhesive layer 18, the adhesive layer 18, the support film 17 and the abrasive cleaning gel 14 constitute an abrasive cleaning gel film 19 which is commercially available.

The abrasive cleaning gel film 19 is attached to an upper surface of an ultrasonic diaphragm 20. A plurality of plate-mounted ultrasonic transducers 21 are provided on a lower surface of the ultrasonic diaphragm 20. Both ends of the ultrasonic diaphragm 20 are fixed to a mounting base 22 by bolts (not shown).

Each of the plate-mounted ultrasonic transducers 21 is supplied with an energy and a signal of ultrasonic vibration from an ultrasonic oscillator 24 via a cable 23, so that the ultrasonic diaphragm 20 is vibrated in a direction indicated by an arrow 25.

When the vertical probe head 13 moves up and down at a constant speed in the directions of the arrows 26 and 27, the worn tip 4w is regenerated into a sharp conical shape. The operation will be described with reference to FIG. 4.

In FIG. 4, when the abrasive cleaning gel 14 vibrations ultrasonically in the direction of the arrow 25, the abrasive grains 15 also vibrate ultrasonically in a direction indicated by an arrow 28. Due to the ultrasonic vibration of the abrasive grains 15, the tip of the wire probe 1 is subjected to repeated collisions with the abrasive grains 15, and is subjected to the mechanical etching.

When the wire probe 1 is moved up and down in the directions of the arrows 26 and 27 at the constant speed, the closer to the tip of the probe 1, the higher the frequency of the mechanical etching. That is, the tip 4w is repaired to have the conical shape. Thus, as shown in FIG. 5, the tip of the probe is repaired to have the sharp conical shape as shown in 4r of FIG. 5.

The vibration amplitude and the frequency of the ultrasonic vibration 25 are 30 microns (both amplitudes) and 25 kHz, respectively even when a general commercially available ultrasonic transducer is used. The vibration speed of the ultrasonic vibration is calculated in order to show the effect of the present invention.

Since the ultrasonic vibration is sinusoidal, the effective speed is expressed as V=rω/(√2). Thus, the effective speed is

V=0.015 mm×2π×25,000/sec/(√2)=1,665 mm/sec=about 100 m/min.

Comparing the above speed with a speed of general whetstone polishing, it is comparable to high-speed polishing. That is, the speed of the mechanical etching according to the present invention is high, and the highly efficiency mechanical etching is possible.

The embodiment of the present invention has been described with emphasis on repairing the worn tip of the probe. However, the abrasive cleaning gel 14 is also used for cleaning debris adhered to the tip of the probe. Since the present invention has the high efficiency mechanical etching feature, it is possible to reliably remove the debris in a short time even in the cleaning of the debris fixed to the tip of the probe.

The effects of the present invention are summarized below.
(1) It is possible to repair a shape of a tip of a probe made of a rare metal which is difficult to be chemically etched.
(2) The chemical etching leading to environmental pollution is unnecessary.
(3) It is possible to clean the tip of the probe and restore the shape of the tip in a short time by the mechanical etching using high-speed and high-efficiency ultrasonic vibration. As a result, the downtime of the expensive prober is reduced, which contributes to cost reduction and operation rate improvement of the semiconductor test process.

### EXPLANATION OF REFERENCE NUMERALS

1 Wire probe
2 Pin
3 Insulating coating
4n Tip before wear out
4w Worn tip
4r Shape-repaired tip
5 Lower aperture plate
6 Through hole
7a, 7b Connecting member
8 Upper aperture plate
9 Through hole
10 Upper electrode plate
11 Printed circuit board
12a, 12b Spacer
13 Vertical probe head
14 Abrasive cleaning gel
15 Abrasive grains
16 Fluid in gel form
17 Support film
18 Adhesive layer
19 Abrasive cleaning gel film
20 Ultrasonic diaphragm
21 Plate-mounted ultrasonic transducer
22 Mounting base
23 Cable
24 Ultrasonic oscillator
25 Ultrasonic vibration
26 Arrow
27 Arrow
28 Ultrasonic vibration of abrasive grains
(29 to 50: Missing number)
51 Probe
51w Probe requiring regeneration
52 (Missing number)
53 Straight pin
54 Conical shape of tip
54w Worn tip cone
54r Regenerated conical tip
55 Table
56 Container
57 Chemical etchant
58 Arrow
59 Arrow
60 Abrasive cleaning gel
61 Abrasive grains
62 Fluid in gel form
63 Support film
64 Adhesive layer
65 Abrasive cleaning gel film
66 Arrow

1. A method and an apparatus for forming a tip of a probe for test into a conical shape, wherein under the conditions that an abrasive cleaning gel film having an abrasive cleaning gel layer and being configured to be stuck to a surface is adhered to a vibrating surface of an ultrasonic transducer and is ultrasonically vibrated, and an axial direction of the probe is matched with a vibrating direction of the ultrasonic transducer, an operation, in which the tip of the probe is penetrated to a predetermined depth in the abrasive cleaning gel layer at a constant speed and then pulled up at a constant speed, is performed one or more times to form the tip of the probe into the conical shape.

2. A method and an apparatus for forming a tip of a probe for test into a conical shape, wherein under the conditions that a container having a shallow bottom is fixed to a vibrating surface of an ultrasonic transducer and is filled with a viscous fluid or a gel fluid in which fine abrasive grains are mixed and dispersed to form a viscous fluid or gel fluid layer therein, and an axial direction of the probe is matched with a vibrating direction of the ultrasonic transducer, an operation, in which the tip of the probe is penetrated to a predetermined depth in the viscous fluid or gel fluid layer at a constant speed and then pulled up at a constant speed, is performed one or more times to form the tip of the probe into the conical shape.
